(19) United States
(12) Patent Application Publication
(10) Pub. No.: US 2026/0210517 A1
(43) Pub. Date: Jul. 23, 2026

(54) FLAT MICRO-LED FOR TAILLIGHT

(71) Applicant: VueReal Inc., Waterloo (CA)

(72) Inventors: Gholamreza CHAJI, Waterloo (CA); John CRONIN, Jericho, VT (US)

(73) Assignee: VueReal Inc., Waterloo, ON (CA)

(21) Appl. No.: 19/142,261

(22) PCT Filed: Dec. 21, 2023
(86) PCT No.: PCT/CA2023/051733

§ 371 Date: Jun. 23, 2025

Related U.S. Application Data
(60) Provisional application No. 63/477,026, filed on Dec. 23, 2022.

(51) Int. Cl. F21S 43/19; F21S 43/14; F21S 43/30; F21S 45/10; F21W 103/20; F21W 103/30; F21W 103/35; H10H 29/24; H10H 29/85

(52) U.S. Cl. CPC F21S 43/195; F21S 43/14; F21S 43/30; F21S 45/10; H10H 29/24; H10H 29/8508; F21W 2103/20; F21W 2103/30; F21W 2103/35

(57) ABSTRACT

A Micro-LED-based vehicle taillight. Micro-LEDs may be arranged in a panel with density to create the same or similar intensity light as existing taillight designs or to conform with legal requirements. These Micro-LED taillights may allow for cheaper, more energy efficient, smaller, and/or more customizable taillights.

### BACKGROUND AND FIELD OF THE DISCLOSURE

The present disclosure is generally related to micro-LED lighting in automotive applications.

Due to the required brightness of vehicle taillights, they often take up a large amount of volume of the back of a vehicle.

Taillights can be costly, especially on larger vehicles or vehicles with computerized taillight control.

Taillights produce heat as a byproduct of generating light. This heat is wasted energy and can be harmful to the vehicle and human operators.

Taillights can be cumbersome and weighty, reducing the vehicle's speed, gas efficiency, and aerodynamics. While also making them more costly to store and transport.

While not the most expensive part of a vehicle to replace, taillights can still be costly, depending on what kind of taillight technology a vehicle uses. Some bulbs may be as expensive as $100 to replace each, and some traditional LED taillights can require entire taillight assembly replacement.

### SUMMARY

The present invention relates to a method to integrate Micro-LEDs into a vehicle taillight, the method comprising, having a Micro-LED panel comprised of a plurality of Micro-LEDs, bounding a substrate to a Micro-LED tile, a connector which allows electronics of the Micro LED panel to integrate with a vehicle and having the Micro-LED panel perform a function of a vehicle taillight.

### DESCRIPTIONS OF THE DRAWINGS

FIG. 1: Illustrates an integration of a transferred microdevice with an electro-optical thin film device in a hybrid structure, according to an embodiment.

FIG. 2: Illustrates a flat Micro-LED panel for a taillight, according to an embodiment.

FIG. 3: Illustrates a flat Micro-LED panel for a taillight with multiple Micro-LED patterns, according to an embodiment.

FIG. 4: Illustrates a flat Micro-LED panel for a taillight, according to an embodiment.

FIG. 5: Illustrates Micro-LED tiles configured to perform smarter aesthetic tailgate functions by the manufacturer, according to an embodiment.

FIG. 6: Illustrates a flat Micro-LED panel for a taillight with multiple user-selected Micro-LED tile patterns, according to an embodiment.

FIG. 7: Illustrates a flat Micro-LED panel for a taillight capable of visible light communication (VLC)., according to an embodiment.

FIG. 8: Illustrates Micro-LED panels embedded in reflectors in the taillight for enhanced direction and intensity, according to an embodiment.

### DETAILED DESCRIPTION

Embodiments of the present disclosure will be described more fully hereinafter with reference to the accompanying drawings in which like numerals represent like elements throughout the several figures, and in which example embodiments are shown. Embodiments of the claims may, however, be embodied in many different forms and should not be construed as limited to the embodiments set forth herein. The examples set forth herein are non-limiting examples and are merely examples among other possible examples. Embodiments also relate to structure, systems and methods of interior and exterior lighting in automobiles.

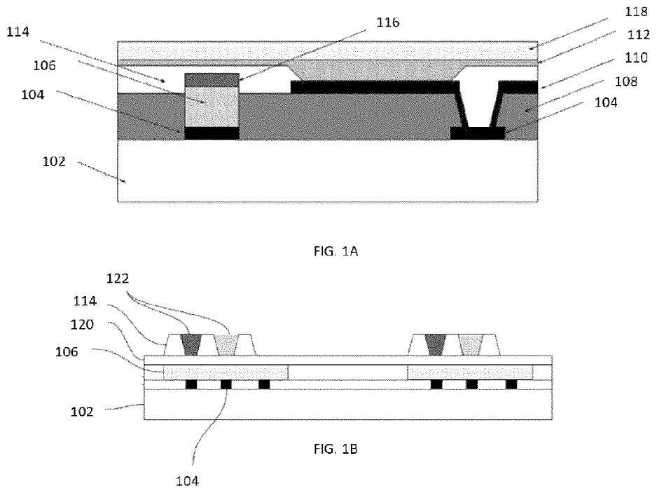

FIG. 1A shows an example of integrating a transferred microdevice 106 with an electro-optical thin film device 112 in a hybrid structure. This is an example of an integrated micro-led tile that is later picked and placed into an array of tiles. It should be obvious to those in the art there are many ways to create micro-led tiles and integrate them in an array of tiles, as per US20160218143A1—Microdevice integration into system substrate. A receiver substrate 102 and contact pads 104 upon which the microdevice 106 arrays are transferred and into which the thin film electro-optical device is integrated in a number of hybrid structure embodiments. Microdevice 106 may be transferred and bonded to the bonding pad 104 of the receiver substrate 100. In one case, a dielectric layer 108 is formed over the substrate 102 to cover the exposed electrodes and conductive layers. Lithography and etching may be used to pattern the dielectric layer 108. Conductive layer 110 is then deposited and patterned to form the bottom electrode of the thin film electro-optical device 112. If there is no risk of unwanted coupling between bottom electrode 110 and other conductive layers in the receiver substrate, the dielectric layer 108 may be eliminated. However, this dielectric layer can also act as a planarization layer to offer better fabrication of of the electrode 110 and the microdevice 106. Thin film electro-optical device 112 is then formed over this structure. Organic LED (OLED) devices are an example of a thin film electro-optical device that may be formed using different techniques, including but not limited to shadow mask, lithography, and printing patterning. Finally, the top electrode 118 of the electro-optical thin film device 112 is deposited and patterned if needed. In an embodiment where the microdevices' 106 thickness is significantly high, cracks or other structural problems may occur within the bottom electrode 110. In these embodiments, a planarization layer may be used in conjunction with or without the dielectric layer 108 to address this issue. In another embodiment, the microdevice 106 can have a device electrode 116. This electrode can be common between other microdevices 106 in the system substrate. In this case, the planarization layer (if present) and/or bank structure 114 covers the electrode 116 to avoid any shorts between the electro-optical device 112 and device electrode 116.

FIG. 1B illustrates structures where the device is shared between a few pixels (or sub-pixels) after post-processing to deposit a common electrode and color conversion layers. Here the microdevice 106 is not fully patterned, but the horizontal condition is engineered so that the contacts 104 define the area allocated to each pixel. The system substrate 102 with contact pads 104 and a donor substrate with microdevices 106. After the microdevices 106 are transferred to system substrate 102, one can do post-processing, such as depositing common electrode 120, color conversion layers 122, color filters, and so on. However, the methods described in this disclosure and other possible methods can be used. It is possible to add the color conversion layers as described into pixel (or sub-pixel) active areas after forming the active area. This can offer a higher fill factor and higher performance and avoid color leaking from the side pixel (or sub-pixel) if the active area of the pixel (or sub-pixel) is covered by reflective layers. The microdevices 106 are grown on a buffer/sacrificial layer in another embodiment.

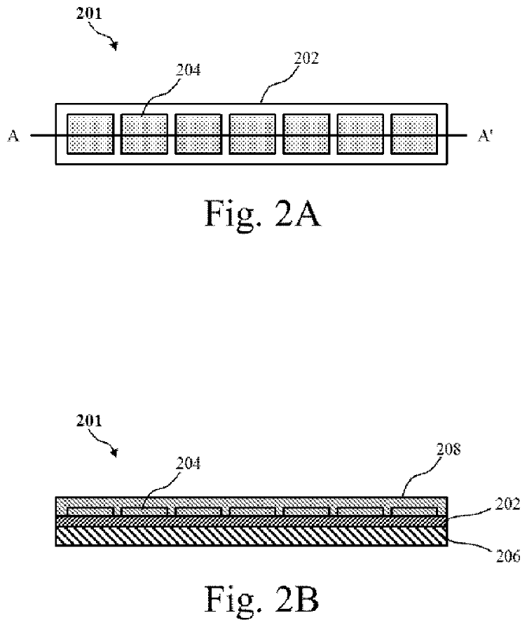

FIG. 2A displays a flat Micro-LED panel for a taillight. FIG. 2B a cross-section of the Micro-LED panel of FIG. 2A along the line A-A′. Element 202 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing taillights. The panel may use RGB Micro-LEDs, which may be programmable to display multiple colors. Element 204 may be a substrate to which the Micro-LED tiles may be bound. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. Element 206 may be a Micro-LED tile comprised of multiple Micro-LEDs. Element 208 may be an adhesive strip allowing the Micro-LED panel to adhere, or otherwise connect to, the vehicle. Element 210 may be a protective layer. The protective layer may protect from environmental and/or vibrational damage. The protective layer may be made of glass, epoxy, plastic, metal, other protective materials, or any combination of protective materials. The protective layer may be hermetically sealed. The Micro-LED panel may be closer to the outside of the vehicle than a typical taillight bulb, thereby reducing the space required for taillights. While the initial costs of Micro-LED taillights may be more than traditional taillights, costs may be saved in other areas, such as replacement costs and energy costs. Micro-LEDs are more efficient than traditional taillights and produce less heat, and waste less energy. Because of the reduced required volume, Micro-LED taillights may be lighter than their traditional counterparts. The replacement costs for Micro-LED taillights may be less than other taillights due to the small size of the Micro-LED panel, meaning replacement is likely to be less invasive and may be easy enough to do without vehicle maintenance expertise.

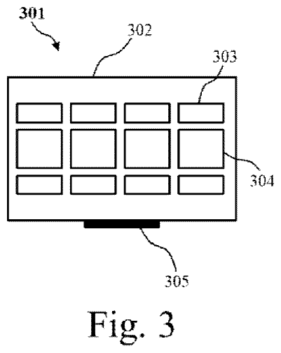

FIG. 3 displays a flat Micro-LED panel for a taillight with multiple Micro-LED patterns. Element 301 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing taillights. The panel may use RGB Micro-LEDs or Blue Micro-LEDs with Phosphorus to get white light. Different shapes of Micro-LED tiles can be used to create patterns. These patterns may be used for the aesthetics of the final light being cast, organizing light patterns, such as high beams or low beams, or indicating directions (left or right) when these specific tiles are activated. Element 302 may be a substrate to which the Micro-LED tiles may be bound. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. Element 303 may be the first type of Micro-LED tile comprised of multiple Micro-LEDs. For example, these Micro-LED tiles may work as break lights and be colored red. Element 304 may be a second type of Micro-LED tile comprised of multiple Micro-LEDs with a shape, structure, color, or other distinguishing factors, that differs from the first type of Micro-LED tile. For example, these Micro-LED tiles may be turn signal lights and hazard lights and may be colored orange, and may be programmed to blink. Element 305 may be a connector which allows the electronics of the Micro-LED panel of FIG. 3 to connect to the electronics system of the vehicle. This may allow the Micro-LED panel to be powered and controlled by the vehicle and to give feedback information to the vehicle. The Micro-LED panel may be closer to the window or lens than a typical taillight bulb, thereby reducing the space required for taillights. While the initial costs of Micro-LED taillights may be more than traditional taillights, costs may be saved in other areas, such as replacement costs and energy costs. Further, the patterned Micro-LED taillight may serve multiple functions and replace more than one light on a vehicle. For example, the Micro-LED panel may act as a taillight and a turn signal light. Micro-LEDs are more efficient than traditional taillights and produce less heat and waste less energy. Because of the reduced required volume, Micro-LED taillights may be lighter than their traditional counterparts. The replacement costs for Micro-LED taillights may be less than other taillights due to the small size of the Micro-LED panel, meaning replacement is likely to be less invasive and may be easy enough to do without vehicle maintenance expertise.

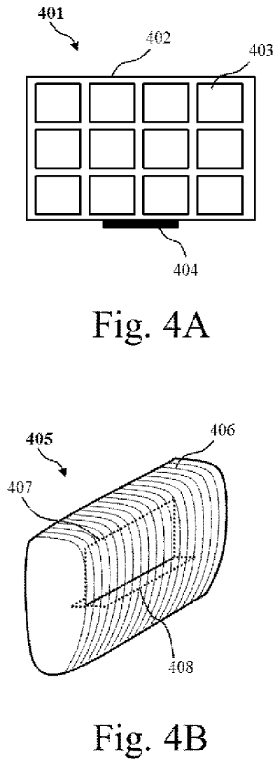

FIG. 4A displays a flat Micro-LED panel for a taillight. FIG. 2B displays a structure which may contain the Micro-LED panel of FIG. 2A. Element 401 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing taillights. The panel may use RGB Micro-LEDs. The light intensity from the Micro-LED panel may be programable and change based on input. For example, the intensity of red break lights may increase based on the breaking force. A driver only applying a small pressure to the brakes may cause a low intensity but still visible signal light. Whereas a driver breaking rapidly may cause a high-intensity red light to indicate to the following driver that a full stop is imminent. The Micro-LED panel may be programmed for visual light communication (VLC) to transmit data from the Micro-LED panel to a receiver. The Micro-LED may transmit road conditions or hazards ahead to the following vehicle or driving instructions to a towed trailer with automatic steering. Element 402 may be a substrate to which the Micro-LED tiles may be bound. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. Element 403 may be a Micro-LED tile comprised of multiple Micro-LEDs. Element 404 may be a connector which allows the electronics of the Micro-LED panel of FIG. 4A to connect to the electronics system of the vehicle. This may allow the Micro-LED panel to be powered and controlled by the vehicle and to give feedback information to the vehicle. Element 405 may be a structure that houses the Micro-LED panel of FIG. 4A. This structure may conform to the shape of taillights in existing or upcoming car models, such that they could be interchanged with non-Micro-LED taillights. Element 406 may be a window that allows the light from the Micro-LEDs through. The window may comprise glass, plastic, crystal, transparent or semi-transparent material, or any combination of these materials. The window may contain lenses or patterns which may diffuse, focus, polarize, block, redirect, or otherwise interact with the light coming from the Micro-LEDs. Element 407 may be the Micro-LED panel of FIG. 4A. Element 408 may be a stand or base which holds the Micro-LED Panel in place with respect to the vehicle. The stand or base may also ensure that the electronic connection between the Micro-LED panel and the vehicle is not broken. The Micro-LED panel may be closer to the window than a typical taillight bulb, thereby reducing the space required for taillights. While the initial costs of Micro-LED taillights may be more than traditional taillights, costs may be saved in other areas, such as replacement costs and energy costs. Micro-LEDs are more efficient than traditional taillights and produce less heat, and waste less energy. Because of the reduced volume required, Micro-LED taillights may be lighter than their traditional counterparts. The replacement costs for Micro-LED taillights may be less than other taillights due to the small size of the Micro-LED panel, meaning replacement is likely to be less invasive and may be easy enough to do without vehicle maintenance expertise.

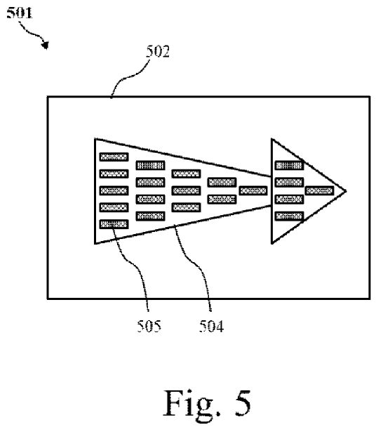

FIG. 5 displays Micro-LED tiles configured to perform smarter aesthetic tailgate functions by the manufacturer. Element 501 may be a Micro-LED panel comprised of one or more tiles containing multiple Micro-LEDs on or in the shaped glass. The Micro-LED tiles may be embedded or otherwise integrated into the shaped glass. The Micro-LED tiles may be fixed to a flexible substrate which is then laminated or otherwise adhered to the shaped glass. Multiple small Micro-LED tiles can be integrated together into a larger flat plate. The panel may contain Micro-LEDs in the density to create the same light as the existing taillights. The panel may use RGB Micro-LEDs or Blue Micro-LEDs with Phosphorus to get white light. Element 502 may be a substrate to which smaller shaped substrates are bound. The substrate may be silicon, glass, sapphire, any other substrate known in the art, any material to which other substrates can be bound, or any combination of these materials. Element 504 may be a shaped substrate to which the Micro-LED tiles may be bound. The substrate's shape may indicate turn or stop or hazard signals (arrow, circle, etc.) based on the manufacturers'design for best aesthetics. One or more of these shaped substrate regions may be part of the larger substrate. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. Element 505 may be a Micro-LED tile comprised of multiple Micro-LEDs. The Micro-LED panel may be closer to the window than a typical taillight bulb, thereby reducing the space required for taillights. While the initial costs of Micro-LED taillights may be more than traditional taillights, costs may be saved in other areas, such as replacement costs and energy costs. Further, the shaped Micro-LED taillight may serve multiple functions and replace more than one light on a vehicle. For example, the Micro-LED panel may have multiple shaped substrate regions, one that acts as a taillight and another that acts as a turn signal light. Micro-LEDs are more efficient than traditional taillights and produce less heat and waste less energy. Because of the reduced required volume, Micro-LED taillights may be lighter than their traditional counterparts. The replacement costs for Micro-LED taillights may be less than other taillights due to the small size of the Micro-LED panel, meaning replacement is likely to be less invasive and may be easy enough to do without vehicle maintenance expertise.

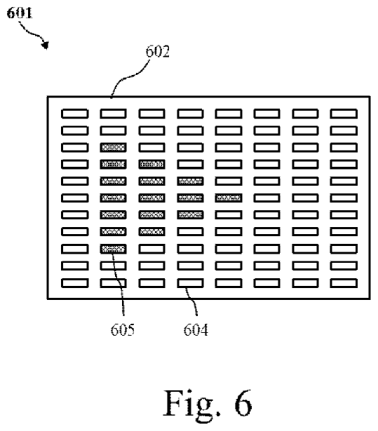

FIG. 6 displays a flat Micro-LED panel for a taillight with multiple user-selected Micro-LED tile patterns. Element 601 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing taillights. The panel may use RGB Micro-LEDs or Blue Micro-LEDs with Phosphorus to get white light. Different groups of Micro-LED tiles can be used to create patterns. These patterns may be used for the aesthetics of the final light being cast, organizing light patterns, such as high beams or low beams, or indicating directions (left or right) when these specific tiles are activated. A user may select which Micro-LED tiles are part of a pattern. For example, the user may select Micro-LED tiles that make an arrow shape, as shown in FIG. 6. The user may assign this pattern to indicate a turn signal. The user may be able to fully customize the pattern or select from approved patterns, for example, where there are legal requirements for the appearance of a turn signal. The user may be able to customize the brightness and color of the Micro-LED tiles. Element 602 may be a substrate to which the Micro-LED tiles may be bound. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. Element 604 may be a Micro-LED tile comprised of multiple Micro-LEDs that are not part of the user-selected pattern. Element 605 may be a Micro-LED tile comprised of multiple Micro-LEDs that is part of the user-selected pattern. The Micro-LED panel may be closer to the window than a typical taillight bulb, thereby reducing the space required for taillights. While the initial costs of Micro-LED taillights may be more than traditional taillights, costs may be saved in other areas, such as replacement costs and energy costs. Further, the patterned Micro-LED taillight may serve multiple functions and replace more than one light on a vehicle. For example, the Micro-LED panel may act as a taillight and turn signal light. Micro-LEDs are more efficient than traditional taillights and produce less heat and waste less energy. Because of the reduced required volume, Micro-LED taillights may be lighter than their traditional counterparts. The replacement costs for Micro-LED taillights may be less than other taillights due to the small size of the Micro-LED panel, meaning replacement is likely to be less invasive and may be easy enough to do without vehicle maintenance expertise.

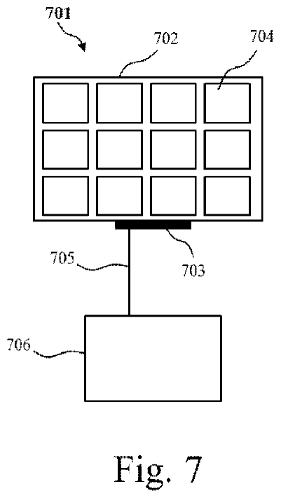

FIG. 7 displays a flat Micro-LED panel for a taillight capable of visible light communication (VLC). Element 701 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing taillights. The panel may use RGB Micro-LEDs. The light intensity from the Micro-LED panel may be programable and change based on input. For example, the intensity of red break lights may increase based on the breaking force. A driver only applying a small pressure to the brakes may cause a low intensity but still visible signal light. Whereas a driver breaking rapidly may cause a high-intensity red light to indicate to the following driver that a full stop is imminent. The Micro-LED panel may be programmed for visual light communication (VLC), so data can be transmitted from the Micro-LED panel to a receiver. The Micro-LED may transmit road conditions or hazards ahead to the following vehicle or driving instructions to a towed trailer with automatic steering. Element 702 may be a substrate to which the Micro-LED tiles may be bound. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. Element 703 may be a connector that allows the Micro-LED electronics to connect to the bus. Element 704 may be a Micro-LED tile comprised of multiple Micro-LEDs. Element 705 may be a bus that allows the Micro-LED panel's electronics to receive instructions from the VLC controller. Element 706 may be a VLC controller which instructs some or all of the Micro-LED tiles to modulate the intensity of light emitted to encode data. The data may then be received by a photodetector, which converts the light back into an electrical signal that can be processed by a computer or other device. This photodetector may be on the following vehicle or a trailer towed by the vehicle to the Micro-LED panel attached to it. The Micro-LED may transmit road conditions or hazards ahead to the following vehicle or driving instructions to a towed trailer with automatic steering. The Micro-LED panel may be closer to the window than a typical taillight bulb, thereby reducing the space required for taillights. While the initial costs of Micro-LED taillights may be more than traditional taillights, costs may be saved in other areas, such as replacement costs and energy costs. The added benefit of VLC may be worth the premium price, such as saving costs that would be spent on wiring that would normally connect the vehicle to a towed trailer. Insurance companies may incentivize VLC-capable taillights if they are shown to reduce collisions or other incidents. Micro-LEDs are more efficient than traditional taillights and produce less heat and waste less energy. Because of the reduced required volume, Micro-LED taillights may be lighter than their traditional counterparts. The replacement costs for Micro-LED taillights may be less than other taillights due to the small size of the Micro-LED panel, meaning replacement is likely to be less invasive and may be easy enough to do without vehicle maintenance expertise.

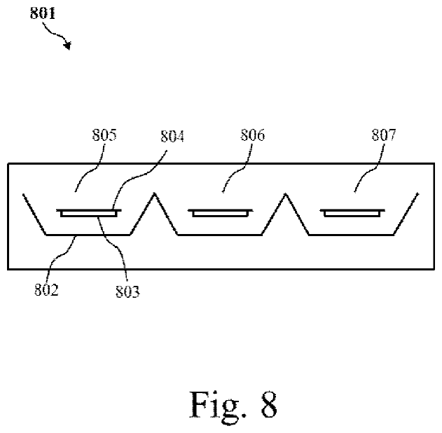

FIG. 8 displays Micro-LED panels embedded in reflectors in the taillight for enhanced direction and intensity. Element 801 may be three Micro-LED panels embedded in reflectors. Each Micro-LED panel may be a different signal, such as stop, turn, or hazard. Element 802 may be a reflector made from highly reflective materials, such as metal or glass. The most common type of reflector is a mirror, made from a sheet of metal or glass coated with a thin layer of a highly reflective material, such as aluminum or silver. Other materials commonly used in reflectors include plastic, ceramic, and various metal alloys. The specific material used in a reflector will depend on the intended application and the desired level of reflectivity. Element 803 may be a Micro-LED panel which may be comprised of one or more tiles that contain multiple Micro-LEDs. Multiple small Micro-LED tiles can be integrated together into a larger flat plate. The panel may contain Micro-LEDs in the density to create the same light as the existing taillights. The panel may use RGB Micro-LEDs. The light intensity from the Micro-LED panel may be programable and change based on input. For example, the intensity of red break lights may increase based on the breaking force. A driver only applying a small pressure to the brakes may cause a low intensity but still visible signal light. Whereas a driver breaking rapidly may cause a high-intensity red light to indicate to the following driver that a full stop is imminent. Element 804 may be a substrate to which the Micro-LED tiles may be bound. The substrate may be silicon, glass, sapphire, any other substrate known in the art, any material to which Micro-LED tiles can be bound, or any combination of these materials. The substrate may further house or be bound to electronics which connect to the Micro-LEDs. These electronics may be contained within the substrate, tunnel through the substrate to reach the Micro-LEDs, or use the substrate as part of the circuit. Element 805 may be a directional region. The reflector and Micro-LED panel in this region may indicate the vehicle will be turning. Element 806 may be a stop region. The reflector and Micro-LED panel in this region may indicate the vehicle is braking. Element 807 may be a hazard region. The reflector and Micro-LED panel in this region may indicate the vehicle's driver has turned on the hazard signal. The Micro-LED panel may be closer to the window than a typical taillight bulb, thereby reducing the space required for taillights. While the initial costs of Micro-LED taillights may be more than traditional taillights, costs may be saved in other areas, such as replacement and energy costs. Further, the regions of the Micro-LED taillight may each replace one or more lights on a vehicle. For example, the Micro-LED panels may act as brakes, hazard, and turn signal lights. Micro-LEDs are more efficient than traditional taillights and produce less heat and waste less energy. Because of the reduced required volume, Micro-LED taillights may be lighter than their traditional counterparts. The replacement costs for Micro-LED taillights may be less than other taillights due to the small size of the Micro-LED panel, meaning replacement is likely to be less invasive and may be easy enough to do without vehicle maintenance expertise. The protective seal may reduce the rate at which the Micro-LED taillight needs to be replaced compared to traditional taillights.

The functions performed in the processes and methods may be implemented in differing orders. Furthermore, the outlined steps and operations are only provided as examples, and some of the steps and operations may be optional, combined into fewer steps and operations, or expanded into additional steps and operations without detracting from the essence of the disclosed embodiments.

What is claimed is:

1. A method to integrate Micro-LEDs into a vehicle taillight, the method comprising:
having a Micro-LED panel comprised of a plurality of Micro-LEDs;
bounding a substrate to a Micro-LED tile;
a connector which allows electronics of the Micro LED panel to integrate with a vehicle; and
having the Micro-LED panel perform a function of a vehicle taillight.

2. The method of claim 1, wherein a first element is a Micro-LED panel which is comprised of one or more Micro-LED tiles containing multiple Micro-LEDs.

3. The method of claim 2, wherein multiple small Micro-LED tiles are integrated together into a larger flat plate.

4. The method of claim 1, wherein the panel comprises Micro-LEDs in a density to create a light at least equivalent to or greater than conventional vehicle taillights.

5. The method of claim 1, wherein the Micro-LED panel uses RGB Micro-LEDs, which are programmable to display multiple colors.

6. The method of claim 1, wherein the substrate is one of silicon, glass, sapphire, or any material to which Micro-LED tiles are bound or any combination of these materials.

7. The method of claim 1, wherein a first element is a connector allowing electronics of the panel to connect to the electronics system of a vehicle wherein further the electronics are contained within the substrate, tunnel through the substrate to reach the Micro-LEDs, or use the substrate as part of a circuit.

8. The method of claim 1, wherein a second element is a protective layer protecting from environmental and/or vibrational damage and wherein further the protective layer is either made of glass, epoxy, plastic, metal or any combination of protective materials and wherein further the protective layer is hermetically sealed.
